(19) United States
(12) Patent Application Publication
(10) Pub. No.: US 2007/0296461 A1
(43) Pub. Date: Dec. 27, 2007

(54) System, method and apparatus for transmitting and receiving a transition minimized differential signal

(75) Inventors: Wayne Wong, Sudbury, MA (US); Mark Sankey, Acton, MA (US); Samuel J. MacMullan, Carlisle, MA (US); Steven S. Fastert, Chelmsford, MA (US); Jeff Winston, Sudbury, MA (US); Tandhoni S. Rao, Ashland, MA (US)

Correspondence Address: FIALA & WEAVER, P.L.L.C.;C/O INTELLEVATE, P.O. BOX 52050, MINNEAPOLIS, MN, 55402, US

(73) Assignee: Radiospire Networks, Inc., Concord, MA (US)

(21) Appl. No.: 11/600,169

(22) Filed: Nov. 16, 2006

Related U.S. Application Data
(60) Provisional application No. 60/816,320, filed on Jun. 26, 2006.

(51) Int. Cl. H03K 19/0175

(52) U.S. Cl. 326/82

(57) ABSTRACT

The present invention is directed to a system, method, and apparatus to transmit/receive TMDS signals using general purpose differential transmitter and receivers. In an embodiment, the general purpose differential transmitter and receivers are designed to operate with differential signaling schemes such as LVDS and LVPECL. In one aspect, embodiments according to the present invention enable the re-configuration of existing and fully-characterized LVDS/LVPECL transmitter/receiver cells to support TMDS (using minimal sets of external components). This provides considerable cost and development time savings, thereby allowing the development of products much more expediently. In another aspect, embodiments according to the present invention provide interfacing methods and systems between differential signaling schemes such as LVDS/LVPECL and TMDS.

### CROSS-REFERENCE TO RELATED APPLICATIONS

The present application claims the benefit of U.S. Provisional Patent Application No. 60/816,320, entitled “System, Method and Apparatus for Transmitting and Receiving a Transition Minimized Differential Signal” and filed on Jun. 26, 2006, the entirety of which is incorporated herein by reference.

### BACKGROUND OF THE INVENTION

1. Field of the Invention

The present invention is generally related to digital communication systems. More particularly, the present invention is directed to a system, method, and apparatus for transmitting and receiving transition minimized differential signals (TMDS) using general purpose differential transmitters and receivers.

2. Background

Electrical component interconnect bandwidth requirements have increased substantially with the evolution of the personal computing and consumer electronics industries. Systems that once employed interfaces capable of supporting transfer rates of 10-50 Mbps now routinely require component interconnect throughputs in excess of 1 Gbps with extremely low transmission error rates.

To meet the simultaneous requirements for greater throughput, higher reliability, and lower power consumption, the industry has increasingly adopted low voltage differential signaling interfaces as a means of component interconnect. Low voltage differential interfaces, such as Low Voltage Differential Signaling (LVDS), Transition Minimized Differential Signaling (TMDS), and Low Voltage Positive Emitter Coupled Logic (LVPECL), have been designed to specifically overcome the common-mode noise, transmission line reflection, and electromagnetic interference (EMI) problems that have limited the rates of single-ended signaling schemes such as Transistor-Transistor Logic (TTL).

Of the low voltage differential interfaces, LVDS is perhaps the most commonly used and has been defined in the ASNI/TLI/EIA-644-A standard. It is effectively the de facto standard LCD display interface within notebook PCs and is used extensively in wireless infrastructure equipment, cameras, copiers, automotive entertainment, and imaging equipment. LVPECL has similar attributes and similar applications and is used in lieu of LVDS when higher voltage swings are required.

Despite the popularity of LVDS and LVPECL there are notable applications where they have not gained traction. One such application is the standardized external audio/video (a/v) cable interface known as Digital Video Interface (DVI) which is mainly used to connect a/v source equipment such as set-top boxes, DVD players and a/v receivers to display devices such as flat panels. DVI and its successor High Definition Media Interface (HDMI) opted to utilize TMDS as the underlying differential signaling interface predominantly because TMDS is more capable of reliably supporting the required throughputs of 1.5-3.0 Gbps at the required interconnect lengths of 5-10 meters.

As a result, LVDS and LVPECL are currently the differential interfaces of choice for most applications, with TMDS being a specialty interface for high-throughput, long-run applications. However, systems with the ability to transmit/receive both LVDS/LVPECL and TMDS will have a competitive advantage over systems dedicated to one or the other type of differential interfaces.

What are needed therefore are a system, method, and apparatus to transmit/receive TMDS signals using general purpose differential transmitters and receivers designed for differential signaling interfaces such as LVDS and LVPECL, for example, and vice versa.

### BRIEF SUMMARY OF THE INVENTION

The present invention is directed to a system, method, and apparatus to transmit/receive TMDS signals using general purpose differential transmitter and receivers. In an embodiment, the general purpose differential transmitter and receivers are designed to operate with differential signaling interfaces such as LVDS and LVPECL.

An embodiment of the present invention enables the re-configuration of existing and fully-characterized LVDS/LVPECL transmitter/receiver cells to support TMDS (using minimal sets of external components). This provides considerable cost and development time savings, thereby allowing the development of products much more expediently.

Additionally, an embodiment of the present invention provides interfacing methods and systems between differential signaling schemes such as LVDS/LVPECL and TMDS.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 illustrates an architecture for coupling a TMDS driver and a LVDS/LVPECL receiver.

FIG. 2 illustrates an example simulated model of a TMDS transmitter to LVDS receiver interconnection.

FIG. 3 illustrates an architecture for coupling a LVDS/LVPECL driver and a TMDS receiver.

FIG. 4 illustrates an example simulated model of a LVDS transmitter to TMDS receiver interconnection.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION OF THE INVENTION

### A. Overview

In the field of interconnect technologies, low voltage differential signaling schemes are heavily employed to meet the simultaneous requirements for high throughput, reliability, and low power consumption. In particular, LVDS (Low Voltage Differential Signaling) and LVPECL (Low Voltage Positive Emitter Coupled Logic) are the differential interfaces of choice for the majority of applications.

However, for applications requiring higher throughputs (1.5-3.0 Gbps) such as applications that employ DVI/HDMI interfaces, TMDS signaling is commonly used.

Currently, various devices including field programmable gate arrays (FPGA) are equipped with built-in general purpose LVDS/LVPECL interfaces. Very few, however, include built-in TMDS interfaces. This is generally due to the fact that the development of custom designs for TMDS transmitter/receiver cells into an ASIC is commercially both costly and time consuming (The TMDS cells must be designed, simulated, verified, tested and characterized for each semiconductor process node).

On the other hand, the re-configuration of existing and fully-characterized LVDS transmitter/receiver cells in ASIC designs to support TMDS (using a minimal set of external components) provides considerable cost and development time savings, thereby allowing the development of products much more expediently.

The present invention is related to a system, method and apparatus for the transmission and/or reception of TMDS signals using general purpose differential transmitters and/or receivers re-configured with a minimal set of external components. In particular the invention is directed to systems and methods to re-purpose LVDS/LVPECL interfaces to realize TMDS transmitters and/or receivers.

### B. Electrical Compatibility

TMDS, LVDS, and LVPECL use differential signaling and are compatible with a 3.3 V power supply voltage. Accordingly, from a power supply perspective, it is feasible that they can be made to interface with each other.

From an operating frequency perspective, the maximum frequency of operation for a TMDS transceiver is 724.5 Mhz and 655 MHz for LVDS. However, since the clock rail for TMDS is defined to be the character clock and not the baud rate clock of the data rails, the maximum TMDS clock frequency is 74.25 Mhz. This implies that the maximum operation frequency for TMDS is determined from the data rails and is 372.25 Mhz. Thus, LVDS is capable of handling the frequency of TMDS signals having a clock rate of 74.25 Mhz or less. Similar analysis shows that LVPECL can handle nominal TMDS signal frequencies as well.

Although there is basic electrical compatibility between TMDS and LVDS/LVPECL from a supply voltage and clock frequency perspective, there are significant incompatibilities with regards to common mode range requirements. For example, the common mode range (the range of the voltage that is common to both differential branches) of a TMDS signal is nominally around 3.1 V. On the other hand, LVDS receivers typically operate using a common mode voltage of 1.2V. Similarly, many LVPECL receivers expect a common mode voltage of 1.2V. This clearly is one area that must be addressed in order to realize an LVDS/LVPECL-based TMDS interface. Similarly, signal swing requirements must be met at both ends of the interface.

### C. TMDS to LVDS/LVPECL Communication

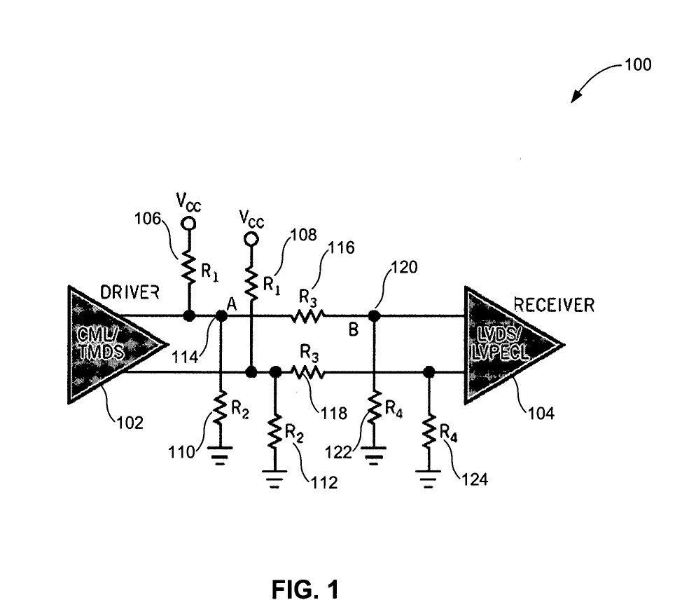

FIG. 1 illustrates an architecture 100 for coupling a TMDS driver and a LVDS/LVPECL receiver. Architecture 100 includes a CML (Current Mode Logic)/TMDS driver 102 and a LVDS/LVPECL receiver 104 coupled by a differential interface. The differential interface ensures that the common mode range and signal swing requirements are met both at the driver and receiver ends of the interface.

Optionally, the differential interface includes an impedance network. In an embodiment, the impedance network includes, for each branch of the differential interface, a first impedance R₁ 106/108 coupled between an output of CML/TMDS driver 102 and a power supply voltage V_{CC}, a second impedance R₂ 110/112 coupled between the output of CML/TMDS driver 102 and ground, a third impedance R₃ 116/118 coupled between the output of CML/TMDS driver 102 and an input of LVDS/LVPECL receiver 104, and a fourth impedance R₄ 122/124 coupled between the input of LVDS/LVPECL receiver 104 and ground.

In FIG. 1, the impedance network is shown according to a resistor network embodiment. As would be appreciated by a person skilled in the art, however, embodiments of the present invention are not limited to the embodiment of FIG. 1 and equivalent resistive, capacitive, and/or inductive networks may also be used.

In an embodiment, the impedance network steps down the common mode voltage of TMDS driver 102 to meet the common mode range of LVDS/LVPECL receiver 104 and ensures that a received signal swing at LVDS/LVPECL receiver 104 is within acceptable range. At the same time, the impedance network provides an appropriate output impedance match for TMDS driver 102.

In an exemplary embodiment, impedances R₁ 106-108, R₂ 110-112, R₃ 116-118, and R₄ 122-124 are assigned values of 50, 100000, 150, and 150 Ohms, respectively.

Referring to FIG. 1, the common-mode voltage at the output node A 114 of CML/TMDS driver 102 is given by:

$${V}_{A} = {V}_{CC} \frac{{R}_{eq}}{{R}_{1} + {R}_{eq}} \qquad ( 1 )$$

where R_{eq} is the equivalent resistance at node A 114, and is given by:

$${R}_{eq} = \frac{{R}_{2} \cdot ( {R}_{3} + {R}_{4} )}{{R}_{2} + ( {R}_{3} + {R}_{4} )} . \qquad ( 2 )$$

Accordingly, given a 3.3 V power supply (V_{CC}), the theoretical value of the common-mode voltage at node A 114 is equal to 2.787 V. This value is within the 3.1 V common-mode voltage range of TMDS.

Similarly, the common-mode voltage at the input node B 120 of LVDS/LVPECL receiver 104 is given by:

$${V}_{B} = {V}_{th\_B} \cdot \frac{{R}_{4}}{{R}_{th\_B} + {R}_{4}} \qquad ( 3 )$$

where Vₜₕ_{_{—}}_{B} and Rₜₕ_{_{—}}_{B} are respectively the Thevenin voltage and resistance calculated with respect to node B (i.e., node B open-circuited). Vₜₕ_{_{—}}_{B} and Rₜₕ_{_{—}}_{B} are given by:

$$\begin{matrix}{V}_{th\_B} = {V}_{CC} \frac{{R}_{2}}{{R}_{1} + {R}_{2}} ; and & ( 4 ) \\ {R}_{th\_B} = {R}_{3} + \frac{{R}_{1} \cdot {R}_{2}}{{R}_{1} + {R}_{2}} . & ( 5 )\end{matrix}$$

Given a 3.3 V power supply (V_{CC}), the theoretical value of the common mode-voltage at node B 120 is equal to 1.394 V. Note that this value is within the 0.5 V to 2.35 V common-mode range of LVDS/LVPECL.

Acceptable signal swing levels can also be achieved using the exemplary impedance values. Theoretically, signal swing level at node B 120 is related to signal swing level at node A 114 according to:

$${V}_{B\_sw} = {V}_{A\_sw} \cdot \frac{{R}_{4}}{{R}_{3} + {R}_{4}} . \qquad ( 6 )$$

Accordingly, with a 400 mV peak-to-peak (p-p) theoretical signal swing level at node A 114, the theoretical signal swing level at node B 120 is equal to 200 mV p-p. Note that both values are within the 500 mV p-p and 200 mV p-p respective requirements for CML/TMDS driver 102 and LVDS/LVPECL receiver 104.

Additionally, the impedance network provides TMDS driver 102 with an output impedance match of approximately 50 Ohms (46.457 Ohms). Theoretically, this can be calculated as:

$${R}_{A} = \frac{( \frac{{R}_{1} \cdot {R}_{2}}{{R}_{1} + {R}_{2}} ) ( {R}_{3} + {R}_{4} )}{( \frac{{R}_{1} \cdot {R}_{2}}{{R}_{1} + {R}_{2}} ) + ( {R}_{3} + {R}_{4} )} \qquad ( 7 )$$

where R_{A} is the output resistance calculated at node A 114.

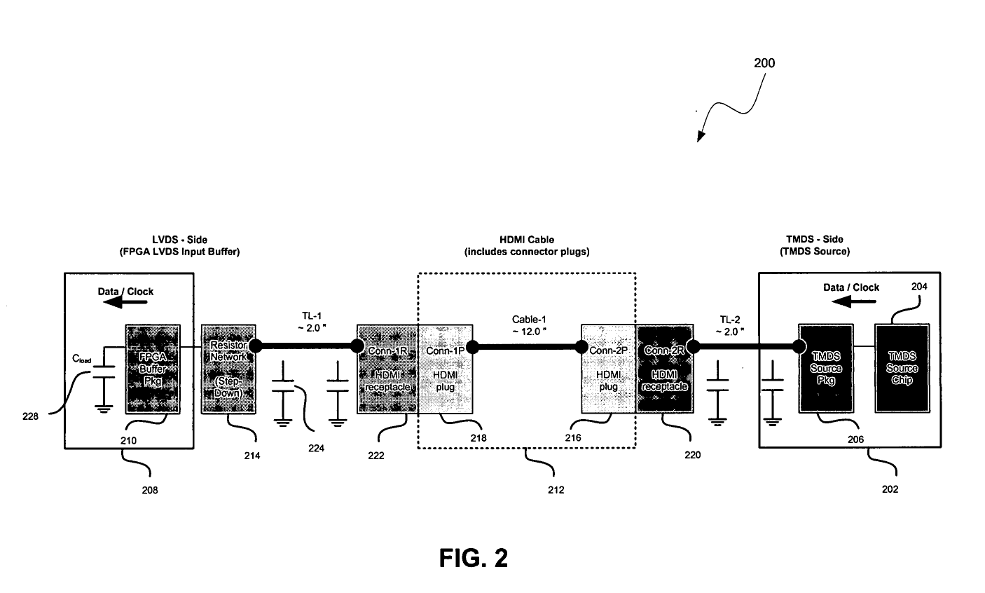

The theoretical calculations above may be further verified using an example simulated TMDS to LVDS interconnection model 200, illustrated in FIG. 2. Simulated model 200 includes a TMDS transmitter 202 simulated using a TMDS source chip 204 and a TMDS Source simulation package 206, a LVDS receiver 208 simulated using a FPGA LVDS Input buffer 210, and an HDMI cable 212 coupling both ends of the interconnection.

A step-down impedance network 214, as described above with respect to FIG. 1, is coupled to FPGA LVDS Input buffer 210. In an embodiment, impedance network 214 is located off-chip. Alternatively, impedance network 214 is integrated within FPGA LVDS Input buffer 210. HDMI cable 212 includes connector plugs 216 and 218 at each end which respectively couple to HDMI receptacles 220 and 222 at each end of the interconnection. Board via capacitances 224 and load capacitance 228 at the LVDS receiver side are also simulated as illustrated in FIG. 2.

In an embodiment, parameter values for simulated TMDS to LVDS interconnection model 200 are given by the following:

| C_via | 0.75 | pF |
|---|---|---|
| Zo | 100 | Ohms |
| Er | 4.0 | |
| W/S/H1/H2 | 5.25/6.75/4.94/9.46 | millimeters |
| R₁ | 55 | Ohms |
| R₂ | High Z, no connect | |
| R₃ | 150 | Ohms |
| R₄ | 150 | Ohms |
| C_{load} | 5 | pF |

where C_via denotes board via capacitance, Zo denotes the characteristic impedance of the transmission line (a differential stripline topology), Er denotes the dielectric constant of the pcb structure, W/S/H1/H2 denote the transmission line geometry (W=width of each of the two lines (differential), S=separation between the two lines, H1=height from the top ground plane to the lines, H2=height of the between the lines and the bottom ground plane), and C_{load} denotes the load capacitance.

### D. L VDS/LVPECL to TMDS Communication

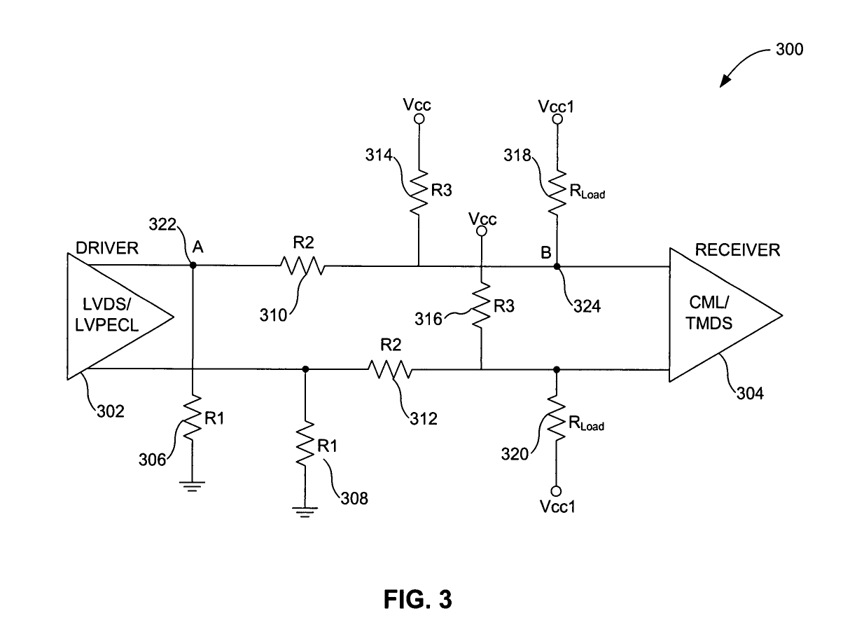

FIG. 3 illustrates an architecture 300 for coupling a LVDS/LVPECL driver and a CML/TMDS receiver. Architecture 300 includes a LVDS/LVPECL driver 302 and a CML/TMDS receiver 304 coupled by a differential interface. The differential interface ensures that the common mode range and signal swing requirements are met both at the driver and receiver ends of the interface.

Optionally, the differential interface includes an impedance network. In an embodiment, the impedance network includes, for each branch of the differential interface, a first impedance R₁ 306/308 coupled between an output of LVDS/LVPECL driver 302 and ground, a second impedance R₂ 310/312 coupled between the output of LVDS/LVPECL driver 302 and an input of CML/TMDS receiver 304, and a third impedance R₃ 314/316 coupled between the input of CML/TMDS receiver 304 and a power supply voltage V_{CC}. A termination impedance R_{load} 318/320 couples the input of CML/TMDS receiver 304 to a power supply voltage V_{CC1}. In an embodiment, the termination impedance is approximately 50 Ohms.

Note that in architecture 300 the impedance network is shown according to a resistor network embodiment. As would be appreciated by a person skilled in the art, however, embodiments of the present invention are not limited to the embodiment of FIG. 3 and equivalent resistive, capacitive, and/or inductive networks may also be used.

In an embodiment, the impedance network steps up the common mode voltage of LVDS/LVPECL driver 302 to meet the common mode range of CML/TMDS receiver 304 and ensures that the received signal swing at CML/TMDS receiver 304 is within acceptable range. At the same time, the impedance network provides an appropriate output impedance match for LVDS/LVPECL driver 302.

In an exemplary embodiment, impedances R₁ 306-308, R₂ 310-312, and R₃ 314-116 are assigned values of 105, 60, and 100 Ohms, respectively.

Referring to FIG. 3, the common-mode voltage at the output node A 322 of LVDS/LVPECL driver 302 is given by:

$${V}_{A} = {V}_{th\_A} \frac{{R}_{1}}{{R}_{1} + {R}_{2} + {R}_{th\_A}} \qquad ( 8 )$$

where Vₜₕ_{_{—}}_{A} and Rₜₕ_{_{—}}_{A} are respectively the Thevenin voltage and resistance calculated with respect to node A 322. Vₜₕ_{_{—}}_{A} and Rₜₕ_{_{—}}_{A} are given by:

$$\begin{matrix}{V}_{th\_A} = {V}_{CC} \frac{{R}_{load}}{{R}_{3} + {R}_{load}} + {V}_{CC 1} \cdot \frac{{R}_{3}}{{R}_{3} + {R}_{load}} & ( 9 ) \\ {R}_{th\_A} = \frac{{R}_{3} \cdot {R}_{load}}{{R}_{3} + {R}_{load}} . & ( 10 )\end{matrix}$$

where R_{load} represents termination impedance 318/320 in FIG. 3.

Accordingly, given a 3.3 V power supply (V_{CC}=V_{CC1}=3.3 V) and a 50 Ohms termination impedance, the theoretical value of the common-mode voltage at node A 322 is equal to 1.747 V. This value is within the 0.5 V to 2.35 V common mode voltage range of LVDS/LVPECL.

Similarly, the common-mode voltage at the input node B 324 of CML/TMDS receiver 304 is given by:

$${V}_{B} = {V}_{CC} \cdot [ \frac{\frac{{R}_{load} \cdot ( {R}_{1} + {R}_{2} )}{{R}_{load} + ( {R}_{1} + {R}_{2} )}}{{R}_{3} + [ \frac{{R}_{load} \cdot ( {R}_{1} + {R}_{2} )}{{R}_{load} + ( {R}_{1} + {R}_{2} )} ]} ] + {V}_{CC 1} \cdot [ \frac{\frac{{R}_{3} \cdot ( {R}_{1} + {R}_{2} )}{{R}_{3} + ( {R}_{1} + {R}_{2} )}}{{R}_{load} + [ \frac{{R}_{3} \cdot ( {R}_{1} + {R}_{2} )}{{R}_{3} + ( {R}_{1} + {R}_{2} )} ]} ] . \qquad ( 11 )$$

Given a 3.3 V power supply (V_{CC}) and a 50 Ohms termination impedance, the theoretical value of the common mode-voltage at node B 324 is equal to 2.745 V. Note that this value is within the 3.1 V common mode voltage range of TMDS.

Acceptable signal swing levels can also be achieved using the exemplary impedance values. Theoretically, signal swing level at node B 324 is related to signal swing level at node A 322 according to:

$${V}_{B\_sw} = {V}_{A\_sw} \cdot [ \frac{\frac{{R}_{3} \cdot {R}_{load}}{{R}_{3} + {R}_{load}}}{{R}_{2} + ( \frac{{R}_{3} \cdot {R}_{load}}{{R}_{3} + {R}_{load}} )} ] . \qquad ( 12 )$$

Accordingly, with a 400 mV peak-to-peak (p-p) theoretical signal swing level at node A 322, the theoretical signal swing level at node B 324 is equal to 143 mV p-p. Note that both values are within the 500 mV p-p and 150 mV p-p respective requirements for LVDS/LVPECL driver 302 and CML/TMDS receiver 304.

Additionally, the impedance network provides LVDS/LVPECL driver 302 with an output impedance match of approximately 50 Ohms (49.412 Ohms). Theoretically, this can be calculated as:

$${R}_{A} = \frac{{R}_{1} \cdot [ {R}_{2} + ( \frac{{R}_{3} \cdot {R}_{load}}{{R}_{3} + {R}_{load}} ) ]}{{R}_{1} + [ {R}_{2} + ( \frac{{R}_{3} \cdot {R}_{load}}{{R}_{3} + {R}_{load}} ) ]} \qquad ( 13 )$$

where R_{A} is the output resistance calculated at node A 114.

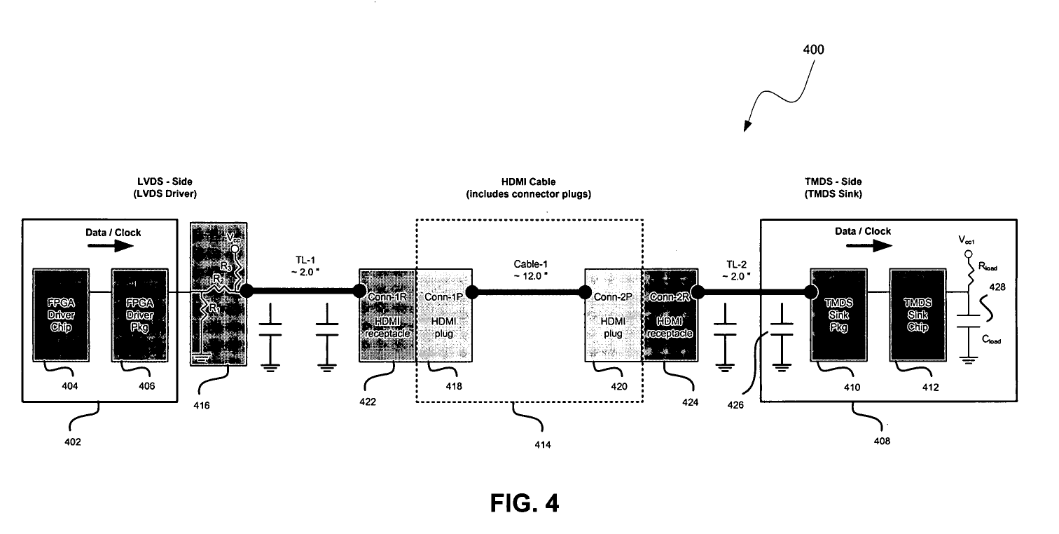

The theoretical calculations above are further verified using an example simulated LVDS to TMDS interconnection model 400, illustrated in FIG. 4. Simulated model 400 includes a LVDS transmitter 402 simulated using a FPGA LVDS Driver chip 404 and a FPGA LVDS Driver simulation package 406, a TMDS receiver 408 simulated using a TMDS sink simulation package 410 and a TMDS sink chip 412, and an HDMI cable 414 coupling both ends of the interconnection.

A step-up impedance network 416, as described above with respect to FIG. 3, is coupled to FPGA LVDS driver 406. In an embodiment, impedance network 416 is located off-chip. Alternatively, impedance network 416 is integrated within FPGA LVDS driver chip 404. HDMI cable 414 includes connector plugs 418 and 420 at each end which respectively couple to HDMI receptacles 422 and 424 at each end of the interconnection. Board via capacitances 426 and load capacitance 428 at the TMDS receiver side are also simulated, as illustrated in FIG. 4.

In an embodiment, parameter values for simulated LVDS to TMDS interconnection model 400 are given by the following:

| C_via | 0.75 | pF |
|---|---|---|
| Zo | 100 | Ohms |
| Er | 4.0 | |
| W/S/H1/H2 | 5.25/6.75/4.94/9.46 | millimeters |
| R₁ | 105 | Ohms |
| R₂ | 60 | Ohms |
| R₃ | 100 | Ohms |
| R_{load} | 50 | Ohms |
| C_{load} | 5 | pF |

where C_via denotes board via capacitance, Zo denotes the characteristic impedance of the transmission line (a differential stripline topology), Er denotes the dielectric constant of the pcb substrate, W/S/H1/H2 denote the transmission line geometry (W=width of each of the two lines (differential), S=separation between the two lines, H1=height from the top ground plane to the lines, H2=height of the between the lines and the bottom ground plane), R_{load} denotes the termination impedance, and C_{load} denotes the load capacitance.

### E. Conclusion

While various embodiments of the present invention have been described above, it should be understood that they have been presented by way of example only, and not limitation. It will be understood by those skilled in the relevant art(s) that various changes in form and details may be made therein without departing from the spirit and scope of the invention as defined in the appended claims. Accordingly, the breadth and scope of the present invention should not be limited by any of the above-described exemplary embodiments, but should be defined only in accordance with the following claims and their equivalents.

What is claimed is:

1. A system for interfacing a Transition Minimized Differential Signaling (TMDS) transmitter and a Low Voltage Differential Signaling (LVDS)/Low Voltage Positive Emitter Coupled Logic (LVPECL) receiver, comprising:
a TMDS driver;
a LVDS/LVPCEL receiver; and
an impedance network coupled between said TMDS driver and said LVDS/LVPCEL receiver, wherein said impedance network steps down a common mode voltage of said TMDS driver to within a defined common mode voltage range of said LVDS/LVPCEL receiver.

2. The system of claim 1, wherein said impedance network controls a signal swing level of said TMDS driver to satisfy a signal swing threshold of said LVDS/LVPCEL receiver.

3. The system of claim 1, wherein said impedance network is a resistive network.

4. The system of claim 1, wherein said impedance network includes one or more resistive, capacitive, and/or inductive elements.

5. The system of claim 1, wherein said impedance network is located off-chip relative to an integrated circuit chip that includes said LVDS/LVPECL receiver.

6. The system of claim 1, wherein said impedance network is integrated with said LVDS/LVPCEL receiver in a single integrated circuit chip.

7. A system for interfacing a Low Voltage Differential Signaling (LVDS)/Low Voltage Positive Emitter Coupled Logic (LVPCEL) transmitter and a Transition Minimized Differential Signaling (TMDS) receiver, comprising:
a LVDS/LVPCEL driver;
a TMDS receiver; and
an impedance network coupled between said LVDS/LVPCEL driver and said TMDS receiver, wherein said impedance network steps up a common mode voltage of said LVDS/LVPCEL driver to within a defined common mode voltage range of said TMDS receiver.

8. The system of claim 7, wherein said impedance network controls a signal swing level of said LVDS/LVPCEL driver to satisfy a signal swing threshold of said TMDS receiver.

9. The system of claim 7, wherein said impedance network is a resistive network.

10. The system of claim 7, wherein said impedance network includes one or more resistive, capacitive, and/or inductive elements.

11. The system of claim 7, wherein said impedance network is located off-chip relative to an integrated circuit chip that includes said LVDS/LVPECL driver.

12. The system of claim 7, wherein said impedance network is integrated with said LVDS/LVPCEL driver in a single integrated circuit chip.

13. A method for interfacing a Transition Minimized Differential Signaling (TMDS) transmitter and a general-purpose receiver, comprising:
receiving a TMDS differential voltage signal from the TMDS transmitter;
decreasing a common-mode voltage of said TMDS differential voltage signal to within a defined common mode voltage range of the general-purpose receiver; and
controlling a swing level of said TMDS differential voltage signal to satisfy a signal swing threshold of the general-purpose receiver.

14. The method of claim 13, wherein a step-down impedance network is coupled between said TMDS transmitter and said general-purpose receiver.

15. The method of claim 14, wherein said step-down impedance network is integrated with said general-purpose receiver in a single device.

16. The method of claim 13, wherein said general-purpose receiver comprises a Low Voltage Differential Signaling (LVDS)/Low Voltage Positive Emitter Coupled Logic (LVPCEL) receiver.

17. A method for interfacing a general-purpose transmitter and a Minimized Differential Signaling (TMDS) receiver, comprising:
receiving a differential voltage signal from the general-purpose transmitter;
increasing a common-mode voltage of said differential voltage signal to within a defined common mode voltage range of the TMDS receiver; and
controlling a swing level of said differential voltage signal to satisfy a signal swing threshold of the TMDS receiver.

18. The method of claim 17, wherein a step-up impedance network is coupled between said general-purpose transmitter and said TMDS receiver.

19. The method of claim 18, wherein said step-up impedance network is integrated with said general-purpose transmitter in a single device.

20. The method of claim 18, wherein said general-purpose transmitter comprises a Low Voltage Differential Signaling (LVDS)/Low Voltage Positive Emitter Coupled Logic (LVPCEL) transmitter.
